(19) United States
(12) Patent Application Publication
(10) Pub. No.: US 2025/0034707 A1
(43) Pub. Date: Jan. 30, 2025

(54) COMBINED REDUCED PRESSURE -HIGH VACUUM PROCESSING CHAMBER

(71) Applicant: Applied Materials, Inc., Santa Clara, CA (US)

(72) Inventors: Mukhles SOWWAN, Sunnyvale, CA (US); Shu-Kwan LAU, Sunnyvale, CA (US); Toshiyuki NAKAGAWA, Narita-Shi (JP)

(21) Appl. No.: 18/632,899

(22) Filed: Apr. 11, 2024

Related U.S. Application Data
(60) Provisional application No. 63/516,121, filed on Jul. 27, 2023.

(51) Int. Cl. C23C 16/455; C23C 16/458

(52) U.S. Cl. CPC C23C 16/45557; C23C 16/4583

(57) ABSTRACT

Embodiments of the disclosure provided herein include an apparatus and system for semiconductor processing. The apparatus includes a processing chamber. The processing chamber includes a substrate support disposed within a processing volume, a controller coupled to the processing chamber, and a carrier and feed ring disposed around the processing volume. The carrier and feed ring includes a ring body, a radical source coupled to at least one ring gas port on a first side of the ring body, and a high-vacuum pump in fluid communication with a ring vacuum port disposed on a second side of the ring body.

### CROSS-REFERENCE TO RELATED APPLICATIONS

This application claims priority to U.S. Patent Application No. 63/516,121, filed Jul. 27, 2023, entitled “COMBINED REDUCED PRESSURE-HIGH VACUUM PROCESSING CHAMBER”, and assigned to the assignee hereof, the contents of which is hereby incorporated by reference in its entirety.

### BACKGROUND

### Field

Embodiments of the present embodiment generally relate to apparatus and systems for semiconductor processing.

### Description of the Related Art

Reduced pressure chemical vapor deposition (RPCVD) is a specialized method of chemical vapor deposition carried out at pressures below atmospheric levels, typically ranging from 1 to 700 Torr. RPCVD offers several advantages over other chemical vapor deposition (CVD) methods. First, at lower pressures, there are fewer gas-phase reactions competing with surface reactions, leading to enhanced film uniformity and purity. Second, longer mean free path of gas molecules at lower pressures results in increased film growth rates. Lastly, lower pressures reduce thermal stress in the film by slowing down heat transfer from the reactor walls to the substrate.

RPCVD finds diverse applications in the growth of thin films for microelectronics, optoelectronics, and other materials science fields. Some specific uses include producing high-quality silicon dioxide (SiO₂) films for gate oxides in metal-oxide-semiconductor field-effect transistors (MOSFETs), silicon carbide (SiC) films for high-power and high-temperature electronics, and diamond films for wear-resistant and optical purposes.

During RPCVD, the substrate is heated to temperatures ranging from 400° C. to 1000° C., and controlled rates of precursor gases are introduced into the reactor. These gases react on the substrate's surface, forming the desired film, which is monitored in real-time using techniques like optical emission spectroscopy or mass spectrometry.

Although RPCVD is a powerful technique with broad applications, it poses certain challenges, especially concerning deposition selectivity. Deposition selectivity refers to the ability to deposit the desired material onto specific regions or substrates while minimizing unwanted deposition on other surfaces. In the case of low-temperature Si and SiGe epitaxy, achieving high selectivity is crucial for precise device fabrication and integration.

The challenge of deposition selectivity arises from the complex surface chemistry and competing reactions during the CVD process. Factors such as surface energies, reactivity, and diffusion rates influence the growth of silicon (Si) and silicon-germanium (SiGe) films on particular substrates or regions.

Accordingly, there is a need for improved systems and methods to address the challenge of deposition selectivity at low temperatures during a CVD process.

### SUMMARY

Embodiments described herein are generally directed to apparatus and systems for semiconductor processing and, more particularly, to apparatus and systems for improved chemical vapor deposition (CVD) onto a substrate.

In an embodiment, a processing chamber is provided. The processing chamber includes a substrate support disposed within a processing volume and a carrier and feed ring disposed around the processing volume. The carrier and feed ring includes a ring body, a radical source coupled to at least one ring gas port on a first side of the ring body, and a high-vacuum pump in fluid communication with a ring vacuum port disposed on a second side of the ring body.

In another embodiment, a system for processing a substrate is provided. The system includes a processing chamber having a processing volume and a substrate support disposed within the processing volume. A carrier and feed ring is disposed within the processing volume of the processing chamber with a radical source coupled to a first side of the carrier and feed ring, a high-vacuum pump coupled to a second side of the carrier and feed ring, and a controller coupled to the processing chamber.

In yet another embodiment, a carrier and feed ring is provided. The carrier and feed ring is configured for processing a substrate within a processing chamber. The carrier and feed ring includes a ring body, a radical source coupled to at least one ring gas port on a first side of the ring body, and a high-vacuum pump coupled to a ring vacuum port disposed on a second side of the ring body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 illustrates a cross-sectional side view of a processing chamber, according to certain embodiments.

FIG. 2A illustrates a perspective view of a carrier and feed ring for the processing chamber of FIG. 1, according to certain embodiments.

FIG. 2B illustrates a side view of the carrier and feed ring for the processing chamber of FIG. 1, according to certain embodiments.

FIG. 2C illustrates a close-up top view of the carrier and feed ring for the processing chamber of FIG. 1, according to certain embodiments.

FIG. 2D illustrates a top view of the carrier and feed ring for the processing chamber of FIG. 1, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein are generally directed to apparatus and systems for semiconductor processing and, more particularly, to apparatus and systems for improved chemical vapor deposition (CVD) onto a substrate.

Reduced pressure CVD (RPCVD) is a specialized method performed below atmospheric pressures (1 to 700 Torr). RPCVD offers advantages such as improved film uniformity and purity due to fewer gas-phase reactions and increased film growth rates from longer gas molecule mean free paths. Lower pressures also reduce thermal stress in the film. RPCVD is used in microelectronics, optoelectronics, and materials science, producing SiO2, SiC, and diamond films.

During RPCVD, a substrate is heated (400° C. to 1000° C.), and precursor gases are introduced into the reactor, reacting on the surface of the substrate to form the desired film, monitored in real-time using techniques like optical emission spectroscopy.

However, RPCVD faces challenges in deposition selectivity, crucial for precise Si and SiGe epitaxy. Complex surface chemistry and competing reactions influenced by surface energies, reactivity, and diffusion rates contribute to these challenges.

The present disclosure provides improved systems and methods for CVD that address the challenges described above by providing a combination reduced-pressure/high-vacuum CVD (RPHVCVD) chamber. In particular, the present disclosure provides a processing chamber including a carrier and feed ring with an integrated high-vacuum pump and a radical source configured to supply at least one atomic radical gas. The carrier and feed ring of the present disclosure is configured to allow the processing chamber to switch between a reduced-pressure environment and a high-vacuum environment. Additionally, the processing chamber is configured for direct injection of radical gas over the surface of the substrate being processed using a carrier gas at high vacuum <10⁻³ Torr.

Embodiments described in the present disclosure provide a clean and controlled environment for film growth by initiating the process with a high vacuum base pressure, resulting in the effective removal of unwanted gases and contaminants from the deposition chamber. This, in turn, minimizes the unwanted gases' and contaminants' impact on the selectivity of film deposition. The working-pressure range is extended, as lower pressures are employed, reducing the presence of impurities and particulates that could potentially interfere with the selectivity of Si and SiGe film growth. Additionally, the embodiments described in the present disclosure enhance the purity of the precursor gases, thus minimizing the likelihood of unintended reactions or contamination on undesired surfaces.

Embodiments described in the present disclosure provide high vacuum by lowering the pressure <10⁻³ Torr, Leading to an increase in the mean free bath of gas molecules and atoms enabling the integration of radical sources, such as thermal gas crackers like H and CI or radio frequency (RF) atom sources, on the epitaxy chamber, facilitating in-situ cleaning and removal of nodules.

In the present disclosure, a “reduced pressure environment” is a processing environment within the processing chamber having an operating pressure of about 1 Torr to about 700 Torr. A “high-vacuum environment” is a processing environment within the processing chamber having an operating pressure of about 10⁻³ Torr or less.

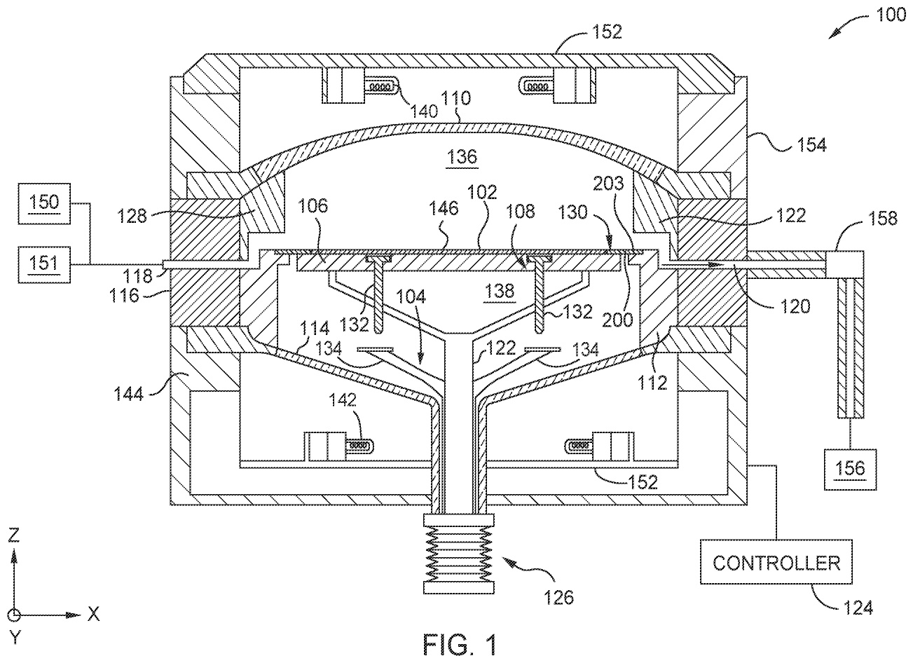

FIG. 1 illustrates a partial schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 146 of the substrate 102.

The processing chamber 100 includes an upper body 154, a lower body 144, and a carrier and feed (CF) ring 116 disposed between the upper body 154 and the lower body 144. The upper body 154, the CF ring 116, and the lower body 144 form at least part of a chamber body. Disposed within the chamber body is a substrate support 106, an upper window 110 (such as an upper dome), a lower window 114 (such as a lower dome), a plurality of upper lamps 140, and a plurality of lower lamps 142. As shown, a controller 124 is in communication with the processing chamber 100 and is used to control processes and methods, such as the operations of the methods described herein.

The substrate support 106 is disposed between the upper window 110 and the lower window 114. The substrate support 106 includes a support face 130 that is configured to support the substrate 102. A lid 152 may include a plurality of sensors (not shown) disposed therein for measuring the temperature within the processing chamber 100. The upper window 110 and the lower window 114 are formed of an energy transmissive material, such as quartz.

A process volume 136 and a purge volume 138 are formed between the upper window 110 and the lower window 114. The process volume 136 and the purge volume 138 are part of an internal volume defined at least partially by the upper window 110, the lower window 114, an upper liner 128, and at least one lower liner 112.

The internal volume has the substrate support 106 disposed therein. The substrate support 106 is attached to a shaft 122. The shaft 122 is connected to a motion assembly 126. The motion assembly 126 includes one or more actuators or adjustment devices that provide movement or adjustment for the shaft 122 or the substrate support 106 within the processing volume 136.

The substrate support 106 may include lift pin holes 108 disposed therein. The lift pin holes 108 are sized to accommodate lift pins 132 for lowering and lifting of the substrate 102 to and from the substrate support 106 before or after a deposition process is performed. The lift pins 132 may rest on lift pin stops 134 when the substrate support 106 is lowered from a process position to a transfer position. The lift pin stops 134 can be coupled to a second shaft 104 through a plurality of arms.

The CF ring 116 includes a plurality of gas inlets 118 and one or more gas exhaust outlets 120. In one or more embodiments, the plurality of gas inlets 118 are disposed on the opposite side of the CF ring 116 from the one or more gas exhaust outlets 120. The upper liner 128 and the lower liner 112 are disposed on an inner surface of the CF ring 116 and protect the CF ring 116 from reactive gases used during deposition operations or cleaning operations. The gas inlet 118 is positioned to flow a gas parallel to the top surface 146 of a substrate 102 disposed within the process volume 136. The gas inlets 118 are fluidly connected to one or more process gas sources 148 and one or more cleaning gas sources 150. The one or more gas exhaust outlets 120 are fluidly connected to an exhaust pump 156. One or more process gases supplied using the one or more process gas sources 148 can include one or more reactive gases (such as one or more of silicon (Si), phosphorus (P), or germanium (Ge)) or one or more carrier gases (such as one or more of nitrogen (N₂) or hydrogen (H₂)). One or more cleaning gases supplied using the one or more cleaning gas sources 150 can include one or more of hydrogen (H) or chlorine (CI). In one or more embodiments, the one or more process gases include silicon phosphide (SiP) or phospine (PH₃), and the one or more cleaning gases include hydrochloric acid (HCl).

The one or more gas exhaust outlets 120 are further connected to or include a high-vacuum pump 158. The high-vacuum pump 158 fluidly connects the one or more gas exhaust outlets 120 and the exhaust pump 156. The high-vacuum pump 158 can assist in the controlled deposition of a layer on the substrate 102. In one or more embodiments, the high-vacuum pump 158 is disposed on an opposite side of the processing chamber 100 relative to the gas inlets 118.

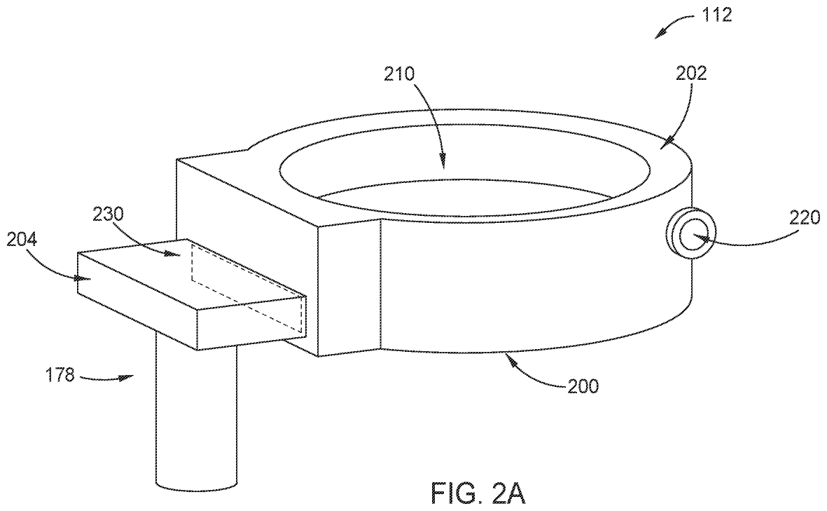

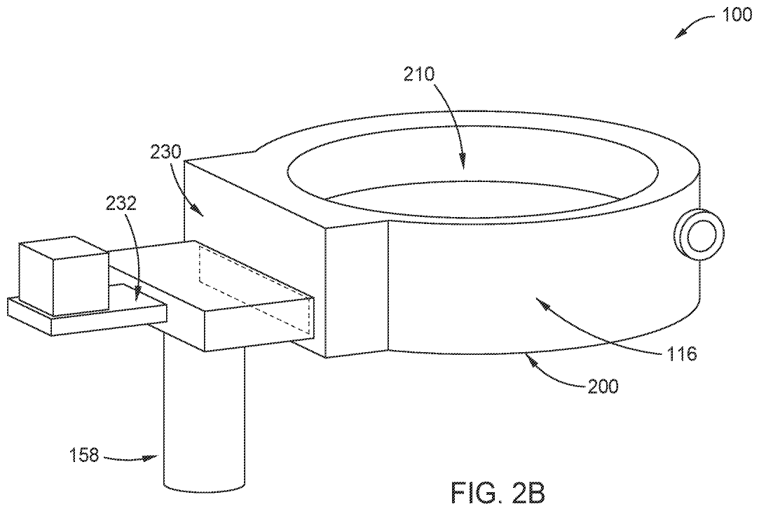

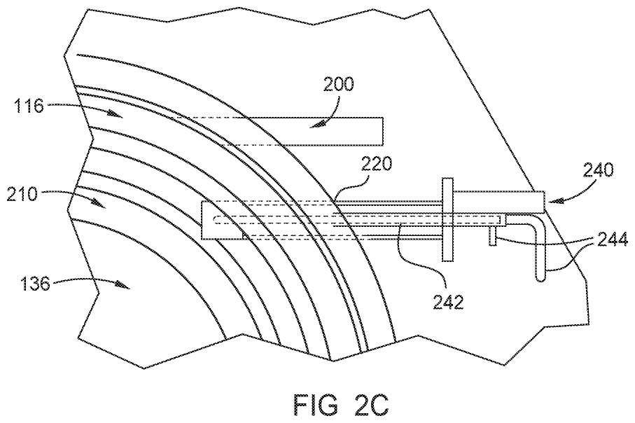

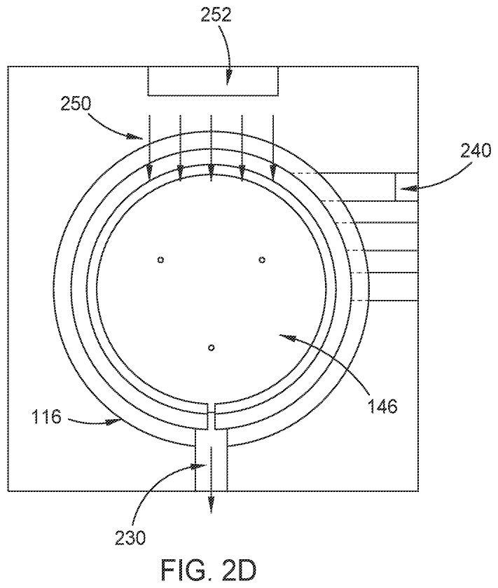

FIG. 2A shows a perspective view of the CF ring 116. The CF ring 116 includes a ring body 200 with a ring aperture 210 through the major surfaces of the ring body 200. The ring aperture 210 allows the CF ring 116 to accommodate the chamber volume. The ring aperture 210 includes at least one ring gas port 220 on a first side 202 along a perimeter of the ring aperture 210. The at least one ring gas port 220 may be in fluid communication with a radical source 240, as shown in FIG. 2C. The ring aperture 210 may also include a ring vacuum port 230 on a second side 204 in fluid communication with the high-vacuum pump 158. The high-vacuum pump 158 may be coupled directly to the ring aperture 210 such that gas passes through the ring aperture 210 and directly into the high-vacuum pump 158. Alternatively, the high-vacuum pump 158 may be disposed at other suitable locations of the processing chamber 100. For example, the high-vacuum pump 158 may be disposed underneath the substrate support 106.

As shown in FIG. 2B, the high-vacuum pump 158 may be coupled to the ring vacuum port 230 through a control valve 232. The control valve 232 is configured to control the vacuum pressure produced by the high-vacuum pump 158 such that the desired vacuum pressure within the processing chamber 100 is achieved. The control valve 232 also allows the processing chamber 100 to switch from a reduced-pressure processing environment to a high-vacuum processing environment.

The high-vacuum pump 158 may be a turbomolecular pump in which gas molecules are expelled from the pump through the use of a rapidly rotating rotor that imparts momentum to them. This process creates or maintains a vacuum by spinning a fan rotor that propels gas molecules from the inlet to the exhaust of the pump. The rotor is composed of lightweight materials, such as titanium or aluminum, and is supported by high-speed bearings. The stator is also constructed from lightweight materials to minimize gas flow resistance.

The high-vacuum pump 158 extends the vacuum pressure down to about 1×10⁻⁸ millibar. By starting with a high-vacuum base pressure, unwanted gases and contaminants are effectively removed from the processing chamber 100, minimizing their influence on deposition selectivity. Further, lower pressure conditions improve film uniformity and control over growth rate. By eliminating gas phase interference and maintaining a stable environment, film properties across the substrate 102 will remain consistent, leading to improved selectivity. The high-vacuum pump 158 also allows the processing chamber 100 to switch between a reduced-pressure processing environment to a high-vacuum environment and reduce the number of particles and byproducts and increase the mean free path of radicals within processing volume 136 to the meter scale.

As shown in FIG. 2C, a radical source 240 may be coupled to the ring gas port 220 of the CF ring 116 and configured to flow atomic radicals into the processing volume 136. In a conventional pre-clean process, only hydrogen (H) radicals are used to etch the away excess particles and byproducts within the processing volume 136. Integrating the radical source 240, such as a thermal gas cracker, into the CF ring 116 enables the use of other atomic radicals for an in-situ pre-clean process that may use a variety of radicals, such as chlorine (CI) or a sequential combination of H and CI, to improve the removal of nodules. The radical source 240 may be an electron beam (E-beam) gas cracker. In an E-beam gas cracker, molecular gases are dissociated at low power levels, rendering them more gas-efficient and less heat-imposing than traditional thermal gas crackers that rely on a hot tungsten filament. To further enhance efficiency and minimize gas load, E-beam gas crackers incorporate a fine-bore inert cracker tube 242 directly connected to gas lines 244.

The radical source 240 may be a single-port cracker or a four-port cracker. The single-port cracker may be used in applications requiring the cracking of a single gas, such as H or CI. The four-port cracker may be used for simultaneously cracking multiple gases, such as embodiments of processing chamber 100 where a sequential H and CI pre-clean is desired. The radical source 240 improves the film deposition, especially when low gas load and high dissociation efficiency are crucial.

As shown in FIG. 2D, the radical source 240 may also be disposed over the top surface 146 of the substrate 102 to provide direct injection of radicals into the processing chamber 100 to minimize recombination. In this setting, the radical source 240 may flow a radical gas, such as H₂ or Cl₂, over the top surface 146 of the substrate 102 using a carrier gas 250 supplied by a carrier gas source 252, such as argon (Ar), for uniform radical distribution over the top surface 146 of the substrate 102. Uniformity of the radical flux across the surface of the top surface 146 of the substrate 102 allows for scalability on a large substrate 102. The flow may be adjusted or switched between viscous flow, as in reduced-pressure environments, and molecular flow, as in high-vacuum environments, to increase the mean free path. The flow may be evacuated from the processing chamber 100 using the high-vacuum pump 158.

As described, the present disclosure provides a CVD system including a carrier and feed (CF) ring between a dome and a susceptor to switch between a reduced pressure mode and a high pressure mode and back. The CF ring introduces a radical source, such as H, Cl, or other radicals, into the chamber, such as by a thermal gas cracker or atom source, for sample cleaning or nodules removal. The CF ring may also introduce other techniques to activate the precursor molecules. Additionally, the CF ring may deposit epitaxial films, including Si and SiGe, under low pressure and high vacuum conditions. The present disclosure also integrates a turbo molecular pump and control valve on the reduced pressure CVD chamber to extend the vacuum pressure down to at least 1×10⁻⁸ mbar. Additionally, the present disclosure integrates an atom (radical) source, such as thermal gas cracker or RF atom source, on a processing chamber for nodule removal. This results in the effective removal of unwanted gases and contaminants from the deposition chamber, minimizing their impact on the selectivity of film deposition.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a substrate support disposed within a processing volume; and
a carrier and feed ring disposed around the processing volume, the carrier and feed ring comprising:
a ring body;
a radical source coupled to at least one ring gas port on a first side of the ring body; and
a high-vacuum pump in fluid communication with a ring vacuum port disposed on a second side of the ring body.

2. The processing chamber of claim 1, further comprising a control valve and wherein the high-vacuum pump is coupled to the ring vacuum port through the control valve.

3. The processing chamber of claim 1, wherein the high-vacuum pump is a turbomolecular pump.

4. The processing chamber of claim 1, wherein the high-vacuum pump is configured to extend a vacuum pressure of the processing volume to 1×10⁻⁸ millibar.

5. The processing chamber of claim 1, wherein the radical source is a thermal gas cracker configured to flow atomic radicals.

6. The processing chamber of claim 5, wherein the atomic radicals include hydrogen, chlorine, or a combination thereof.

7. The processing chamber of claim 1, further comprising a carrier gas source configured to flow a carrier gas over a surface of a substrate disposed within the processing volume.

8. A system for processing a substrate, comprising:
a processing chamber comprising a processing volume and a substrate support disposed within the processing volume, the substrate support configured to support a substrate during processing;
a carrier and feed ring disposed within the processing volume of the processing chamber;
a radical source coupled to a first side of the carrier and feed ring;
a high-vacuum pump coupled to a second side of the carrier and feed ring; and
a controller coupled to the processing chamber.

9. The system of claim 8, further comprising a control valve and wherein the high-vacuum pump is coupled to the carrier and feed ring through the control valve.

10. The system of claim 8, wherein the high-vacuum pump is a turbomolecular pump.

11. The system of claim 8, wherein the high-vacuum pump is configured to extend a vacuum pressure of the processing volume to 1×10⁻⁸ millibar.

12. The system of claim 8, wherein the radical source is a thermal gas cracker configured to flow atomic radicals.

13. The system of claim 12, wherein the atomic radicals include hydrogen, chlorine, or a combination thereof.

14. The system of claim 8, further comprising a carrier gas source configured to flow a carrier gas over a surface of a substrate disposed within the processing volume.

15. A carrier and feed ring configured for processing a substrate within a processing chamber, comprising:
a ring body;
a radical source coupled to at least one ring gas port on a first side of the ring body; and
a high-vacuum pump coupled to a ring vacuum port disposed on a second side of the ring body.

16. The carrier and feed ring of claim 15, further comprising a control valve and wherein the high-vacuum pump is coupled to the ring vacuum port through the control valve.

17. The carrier and feed ring of claim 15, wherein the high-vacuum pump is a turbomolecular pump.

18. The carrier and feed ring of claim 15, wherein the high-vacuum pump is configured to extend a vacuum pressure of a processing volume of a processing chamber to 1×10⁻⁸ millibar.

19. The carrier and feed ring of claim 15, wherein the radical source is a thermal gas cracker configured to flow atomic radicals.

20. The carrier and feed ring of claim 19, wherein the atomic radicals include hydrogen, chlorine, or a combination thereof.
